(19) United States
(12) Patent Application Publication
(10) Pub. No.: US 2022/0267892 A1
(43) Pub. Date: Aug. 25, 2022

(54) FE-PT-BN-BASED SPUTTERING TARGET AND PRODUCTION METHOD THEREFOR

(71) Applicant: TANAKA KIKINZOKU KOGYO K.K., Tokyo (JP)

(72) Inventors: Masahiro Nishiura, Ibaraki (JP); Takamichi Yamamoto, Ibaraki (JP); Kenta Kurose, Ibaraki (JP); Hironori Kobayashi, Ibaraki (JP); Takanobu Miyashita, Ibaraki (JP)

(21) Appl. No.: 17/626,394

(22) PCT Filed: May 22, 2020
(86) PCT No.: PCT/JP2020/020307

§ 371 Date: Jan. 11, 2022

(30) Foreign Application Priority Data
Jul. 12, 2019 (JP) 2019-129820

(51) Int. Cl. C23C 14/34; C22C 32/00; C22C 5/04; C22C 1/05

(52) U.S. Cl. CPC C23C 14/3414; C22C 32/0068; C22C 5/04; C22C 1/051; C22C 1/058

(57) ABSTRACT

A problem of particle generation in an Fe-Pt-BN-based sputtering target having a high relative density is resolved by an approach different from conventional methods.

An Fe-Pt-BN-based sputtering target having a relative density of 90% or more and a Vickers hardness of 150 or less can reduce the number of particles generated during magnetron sputtering.

### TECHNICAL FIELD

The present invention relates to a BN-containing sputtering target to be used for producing a magnetic thin film as well as a production method therefor and particularly relates to an Fe-Pt-BN-based sputtering target containing Fe, Pt, and BN (boron nitride) as well as a production method therefor.

### BACKGROUND ART

As a sputtering target for producing a granular magnetic thin film of a magnetic recording medium in a hard disk drive or the like, a sintered compact containing a ferromagnetic metal of Fe or Co as a main component and a nonmagnetic material, such as SiO₂ or other oxides, B (boron), C (carbon), or BN (boron nitride), has been used. However, BN has problems, for example, of having difficulty in producing a high-density sintered compact due to inferior sinterability, of generating particles during sputtering and thereby lowering the product yield, and of exhibiting poor machinability.

To resolve these problems, a method of aligning the crystal orientation of hexagonal BN by mixing hexagonal BN with metal raw material powders that have been pulverized into the shape of sheets or flakes (Patent Literature (PTL) 1) has been proposed, for example.

Japanese Patent No. 5457615 (PTL 1) discloses that a sintered compact of an Fe-Pt-BN-based magnetic material having an oxygen content as low as 4,000 wtppm or less can be prepared by using Fe—Pt alloy powder; and that the prepared sintered compact exhibits satisfactory machinability and thus can suppress cracking or chipping, thereby reducing the occurrence of abnormal discharge or particle generation. It is also disclosed that the concrete production method includes placing, in a mortar, BN powder and Fe—Pt alloy powder having a particle size of 0.5 μm or more and 10 μm or less, uniformly mixing, hot pressing the resulting mixed powder, and then subjecting to hot isostatic pressing (hereinafter, also referred to as “HIP”). Here, using Fe—Pt alloy powder having a particle size of 0.5 μm or more and 10 μm or less is a prerequisite for converting the form of Fe into the form less susceptible to oxidation. Further, PTL 1 also discloses that the Comparative Examples (Fe-Pt-BN-based, Fe-Pt-BN-nonmagnetic material-based), which were produced under the same production conditions except for mixing Fe powder, Pt powder, and BN powder using a stirred media mill at 300 rpm for 2 hours, exhibit an oxygen content as high as 11,500 wtppm or more, cause chipping, and are unable to reduce the number of particles compared with the Examples.

Japanese Patent No. 5913620 (PTL 2) discloses that stable sputtering is made possible by aligning the crystal orientation of hexagonal BN in one direction, thereby reducing the number of particles; that the orientation of hexagonal BN is aligned as a structure of alternately stacked metal raw materials and hexagonal BN by pulverizing metal raw material powders into the shape of sheets or flakes; and that a mixed powder of the metal raw materials with hexagonal BN is sintered and then subjected to hot isostatic pressing, thereby increasing the relative density of a sintered compact. PTL 2 also discloses that a mixed powder is prepared in an Example by pulverizing metal raw material powders fed into a stirred media mill at 300 rpm for 2 hours, then mixing with hexagonal BN in a V-type mixer, and further mixing using a 100 μm sieve, whereas a mixed powder is prepared in the Comparative Examples by mixing metal raw material powders, without being subjected to pulverization, with hexagonal BN in a mortar. Further, it is also disclosed that the number of particles is less than 360 in the Examples and more than 600 in the Comparative Examples.

Japanese Patent No. 5876155 (PTL 3) discloses a sintered compact sputtering target comprising an alloy having the composition containing 5 to 60 mol % of Pt with the balance being Fe; and a nonmagnetic material dispersed in the alloy, where incorporating at least 5 to 60 mol % of C into the nonmagnetic material and controlling the average particle area of C (carbon) particles to 50 μm² or more and 200 μm² or less on the cross-section perpendicular to the sputtering surface of the sputtering target make it possible to prevent abnormal discharge caused by carbon particle aggregates during sputtering and the resulting increase in the amount of particles generated. To attain the average particle area of C (carbon) particles of 50 μm² or more and 200 μm² or less, it is disclosed that the raw material C powder has a particle size of 200 μm or less and the content of powder having a particle size of 10 μm or less of 10% or less; and that raw material powders excluding C powder are pulverized and mixed using a ball mill or the like for 4 hours, then added with C powder, and classified to separate and remove powder small in particle size. Further, to increase the relative density, it is also disclosed that the raw material powders after sintering are subjected to hot isostatic pressing.

PTL 1 to 3 disclose or suggest nothing about the Vickers hardness of a sputtering target.

### SUMMARY OF INVENTION CITATION LIST

### Patent Literature

PTL 1: Japanese Patent No. 5457615

PTL 2: Japanese Patent No. 5913620

PTL 3: Japanese Patent No. 5876155

### Technical Problem

An object of the present invention is to resolve the problem of particle generation in an Fe-Pt-BN-based sputtering target having a high relative density by an approach different from conventional methods as disclosed in PTL 1 to 3.

### Solution to Problem

The present invention encompasses the following embodiments.

[1] An Fe-Pt-BN-based sputtering target having a Vickers hardness of 150 or less.

[2] The Fe-Pt-BN-based sputtering target according to [1] above, containing 20 mol % or more and less than 40 mol % of Pt and 25 mol % or more and 50 mol % or less of BN, with the balance being Fe and incidental impurities.

[3] The Fe-Pt-BN-based sputtering target according to [1] above, containing 20 mol % or more and less than 40 mol % of Pt, 10 mol % or more and less than 50 mol % of BN, and more than 0 mol % and 30 mol % or less of C, with the balance being Fe and incidental impurities, where a total content of BN and C is 25 mol % or more and 50 mol % or less.

[4] The Fe-Pt-BN-based sputtering target according to any one of [1] to [3] above, further containing one or more elements selected from Au, Ag, B, Cr, Cu, Ge, Ir. Ni, Pd, Rh, and Ru.

[5] The Fe-Pt-BN-based sputtering target according to [4] above, where a total content of one or more elements selected from Au, Ag, B, Cr, Cu, Ge, Ir, Ni, Pd, Rh, and Ru is 15 mol % or less,

[6] The Fe-Pt-BN-based sputtering target according to any one of [1] to [5] above, having a relative density of 90% or more.

[7] A method of producing the Fe-Pt-BN-based sputtering target according to [2] above, including

feeding Fe powder, Pt powder, and BN powder into a stirred media mill and mixing at 100 rpm or more and 300 rpm or less for 1 hour or more and 6 hours or less to obtain a raw material powder mixture; and

sintering the raw material powder mixture, where

hot isostatic pressing (HIP) is not performed.

[8] A method of producing the Fe-Pt-BN-based sputtering target according to [3] above, including

feeding Fe powder. Pt powder. BN powder, and C powder into a stirred media mill and mixing at 100 rpm or more and 300 rpm or less for 1 hour or more and 6 hours or less to obtain a raw material powder mixture; and

sintering the raw material powder mixture, where

hot isostatic pressing (HIP) is not performed.

### Advantageous Effects on Invention

The present invention provides an Fe-Pt-BN-based sputtering target that has a relative density of 90% or more and a, Vickers hardness of 150 or less and that can reduce the number of particles generated during magnetron sputtering.

### BRIEF DESCRIPTION OF DRAWINGS

FIG. 1 is a graph showing the relationship between Vickers hardness (HV) and the number of particles measured in the Examples and the Comparative Examples.

### DESCRIPTION OF EMBODIMENTS

Hereinafter, the present invention will be described in detail with reference to the attached drawing. However, the present invention is by no means limited to these descriptions.

An Fe-Pt-BN-based sputtering target (hereinafter, also simply referred to as “sputtering target” in some cases) of the present invention is characterized by having a Vickers hardness of HV 150 or less, preferably HV125 or less, and more preferably HV120 or less.

As in the Examples and the Comparative Examples described hereinafter, a sputtering target having a Vickers hardness of HV150 or less can suppress generation of particles. Meanwhile, when a Vickers hardness exceeds HV150, more particles are generated. Although the mechanism for enabling suppressed generation of particles at a low Vickers hardness is unclear, it is presumed that a hard metal having a high Vickers hardness damages the inside of BN particles, thereby increasing generation of particles originated from BN.

The Vickers hardness is measured in accordance with JIS 2244. Specifically, a Vickers hardness is obtained by pressing a square-based pyramidal diamond indenter having an angle between opposite faces of 136° into the test surface of a sample under a certain test load (kgf), measuring the surface area S (mm²) of the resulting permanent indentation, and calculating “test load (kgf)/surface area S (mm²) of permanent indentation.”

The sputtering target of the present invention preferably contains 20 mol % or more and less than 40 mol % of N and 25 mol % or more and 50 mol % or less of BN, with the balance being Fe and incidental impurities. Within these ranges, the magnetic characteristics of an FePt-based alloy can be maintained satisfactorily. In addition, according to the production method of the present invention, it is possible to suppress generation of particles since the Vickers hardness of the sputtering target does not become excessively high. Further, BN can act as a grain boundary material in a granular magnetic thin film of a magnetic recording medium.

The sputtering target of the present invention more preferably contains 20 mol % or more and less than 35 mol % of Pt and 30 mol % or more and 45 mol % or less of BN, with the balance being Fe and incidental impurities.

Alternatively, the sputtering target of the present invention preferably contains 20 mol % or more and less than 40 mol % of Pt, 10 mol % or more and less than 50 mol % of BN, and more than 0 mol % and 30 mol % or less of C, with the balance being Fe and incidental impurities, where the total content of BN and C is 25 mol % or more and 50 mol % or less. Within these ranges, the magnetic characteristics of an FePt-based alloy can be maintained satisfactorily. In addition, according to the production method of the present invention, it is possible to suppress generation of particles since the Vickers hardness of the sputtering target does not become excessively high. Further, BN and C can act as grain boundary materials in a granular magnetic thin film of a magnetic recording medium.

The sputtering target of the present invention more preferably contains 20 mol % or more and less than 35 mol % of Pt. 10 mol % or more and less than 40 mol % of BN, and 5 mol % or more and 30 mol % or less of C. with the balance being Fe and incidental impurities, where the total content of BN and C is 25 mol % or more and 45 mol % or less.

The sputtering target of the present invention particularly preferably contains 20 mol % or more and less than 35 mol % of Pt, 10 mol % or more and less than 40 mol % of BN, and 5 mol % or more and 15 mol % or less of C, with the balance being Fe and incidental impurities, where the total content of BN and C is 25 mol % or more and 45 mol % or less.

In a similar manner to BN, C acts as a grain boundary material in a granular magnetic thin film of a magnetic recording medium. By adding C in addition to BN, it is possible to reduce the proportion of metal components and thus to lower a Vickers hardness further.

The sputtering target of the present invention may further contain one or more elements selected from Au, Ag, B, Cr, Cu, Ge, Ir, Ni, Pd. Rh, and Ru. The total content of these additional elements is preferably 15 mol % or less and more preferably 10 mol % or less. Within these ranges, it is possible to satisfactorily maintain the magnetic characteristics of an FePt-based alloy and to maintain the Vickers hardness of HV150 or less for the sputtering target.

The Fe-Pt-BN-based sputtering target of the present invention preferably has a relative density (actual density/theoretical density) of 90% or more. A sputtering target having an excessively low relative density is unfavorable since a desirable film deposition is impossible in some cases when used as a magnetron sputtering target.

Next, a method of producing the Fe-Pt-BN-based sputtering target of the present invention will be described.

The Fe-Pt-BN-based sputtering target of the present invention can be produced by a method, without performing HIP, including feeding Fe powder, Pt powder, BN powder, and C powder if contained into a stirred media mill and mixing at 100 rpm or more and 300 rpm or less for 1 hour or more and 6 hours or less to obtain a raw material powder mixture; and sintering the raw material powder mixture. An excessively low number of rotations in a stirred media mill is unfavorable since uniform dispersion of BN is impossible. Meanwhile, an excessively high number of rotations is also unfavorable since particle generation cannot be suppressed due to formation of fine particles. The number of rotations in a stirred media mill is more preferably 150 rpm or more and 250 rpm or less. An excessively short mixing time through stirring is unfavorable since uniform dispersion of BN is impossible. Meanwhile, an excessively long mixing time is also unfavorable since particle generation cannot be suppressed due to formation of fine particles. The mixing time is more preferably 2 hours or more and 6 hours or less.

A stirred media mill used for obtaining a raw material powder mixture may be any stirred media mill commonly used in the relevant technical field. Examples include horizontal or vertical stirred media mills using, as media, SUS balls, cemented carbide balls, or zirconia balls. Among these, a horizontal or vertical stirred media mill using zirconia balls as media may be used suitably. The atmosphere inside a stirred media mill during mixing is preferably an argon atmosphere to avoid, during mixing, reactions between a mixed powder and a gas inside the stirred media mill.

When one or more additional elements selected from Au, Ag, B, Cr, Cu, Ge, Ir, Ni, Pd, Rh, and Ru are included, additional element powders may be mixed first with Fe powder and Pt powder and then with BN powder and C powder if contained. However, it is preferable to simultaneously mix additional element powders with Fe powder, Pt powder, BN powder, and C powder if contained. When only metal powders are mixed, particles are likely to coarsen, thereby making uniform mixing impossible in some cases.

As Fe powder, a powder having an average particle size of 1 μm or more and 10 μm or less is preferably used. When the average particle size is excessively small, a risk of ignition or the concentration of incidental impurities is likely to increase. Meanwhile, when the average particle size is excessively large, uniform dispersion of BN could be impossible.

As Pt powder, a powder having an average particle size of 0.1 μm or more and 10 μm or less is preferably used. When the average particle size is excessively small, the concentration of incidental impurities is likely to increase. Meanwhile, when the average particle size is excessively large, uniform dispersion of BN could be impossible.

As BN powder, a powder having an average particle size of 2 μm or more and 10 μm or less is preferably used. Outside this range, there are possibilities that a satisfactory dispersion state cannot be achieved, a Vickers hardness could increase, and particle generation cannot be suppressed.

As C powder, a powder having an average particle size of 2 μm or more and 10 μm or less is preferably used. Outside this range, there are possibilities that a satisfactory dispersion state cannot be achieved, a Vickers hardness could increase, and particle generation cannot be suppressed.

As other additional element powders, powders having an average particle size of 0.1 μm or more and 20 μm or less are preferably used. When the average particle size is excessively small, the concentration of incidental impurities is likely to increase. Meanwhile, when the average particle size is excessively large, uniform dispersion could be impossible.

The raw material powder mixture is desirably sintered at a sintering temperature of 600° C. or higher and 1,200° C. or lower and preferably 700° C. or higher and 1,100° C. or lower and a sintering pressure of 30 MPa or more and 120 MPa or less and preferably 50 MPa or more and 100 MPa or less. There is a risk of lowering the relative density at an excessively low sintering temperature or a risk of decomposing BN at an excessively high sintering temperature.

When producing the Fe-Pt-BN-based sputtering target of the present invention, hot isostatic pressing is not performed. Hot isostatic pressing hardens metal components, thereby resulting in an excessively high Vickers hardness. Consequently, as is clear from the Examples and the Comparative Examples described hereinafter, it is impossible to suppress generation of particles.

### EXAMPLES

Hereinafter, the present invention will be described specifically by means of Examples and Comparative Examples. However, the present invention is by no means limited by these examples. The measurement methods for the Vickers hardness, the number of particles, and the relative density of each sputtering target in the following Examples and Comparative Examples are as follows.

[Relative Density]

The relative density is measured by the Archimedes method using pure water as a replacement liquid. An actual density (g/cm³) is determined by measuring the mass of a sintered compact; measuring the buoyant force of the sintered compact (=volume of sintered compact) in the state of floating on the replacement liquid; and dividing the mass (g) of the sintered compact by the volume (cm³) of the sintered compact. The ratio (actual density/theoretical density) to a theoretical density that is calculated on the basis of the composition of the sintered compact is a relative density.

[Number of Particles]

A sintered compact is processed into a diameter of 153 mm and a thickness of 2 mm and bonded using indium to a Cu backing plate having a diameter of 161 mm and a thickness of 4 mm to yield a sputtering target. The resulting sputtering target is fixed to a magnetron sputtering apparatus and subjected to sputtering at an output of 500 W in an Ar gas atmosphere at a gas pressure of 1 Pa for 40 seconds. Subsequently, the number of particles adhered onto a substrate is determined by a particle counter.

[Vickers Hardness]

Vickers hardness is measured in accordance with JIS Z 2244, Specifically, the sputtering surface of a sputtering target is polished with #320 and #1200 SiC abrasive papers, followed by buffing with diamond abrasives having a particle size of 1 μm. By using a Vickers hardness tester (HV-115 from Mitutoyo Corporation), a test load of 2.00 kgf is applied to the resulting sputtering surface through a square-based pyramidal diamond indenter having an angle between opposite faces of 136°. The resulting indentation is observed under a microscope to measure the lengths of two diagonals. Subsequently, the surface area (mm²) of the indentation is calculated to calculate “test load (kgf)/surface area of indentation (mm²).”

### Example 1

To have the composition of 35Fe-35Pt-30BN (molar ratio, the same applies to the remaining Examples section), 172.79 g of Fe powder having an average particle size of 7 μm, 603.60 g of Pt powder having an average particle size of 1 μm, and 65.83 g of BN powder having an average particle size of 4 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact.

After the relative density was measured, the sintered compact was processed into a sputtering target to measure the number of particles and the Vickers hardness. The relative density was 95.0%, the Vickers hardness was HV104, and the number of particles was 67. The results are shown in Table 1.

### Example 2

To have the composition of 32.5Fe-32.5Pt-35BN, 157.91 g of Fe powder having an average particle size of 7 μm, 551.60 g of Pt powder having an average particle size of 1 μm, and 75.58 g of BN powder having an average particle size of 4 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact. Except for this, the relative density, the Vickers hardness, and the number of particles were measured in the same manner as Example 1. The relative density was 94.1%, the Vickers hardness was HV66, and the number of particles was 77. The results are shown in Table 1.

### Example 3

To have the composition of 27.5F′e-27.5Pt-45BN, 129.51 g of Fe powder having an average particle size of 7 μm, 452.40 g of Pt powder having an average particle size of 1 μm, and 94.19 g of BN powder having an average particle size of 4 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact. Except for this, the relative density, the Vickers hardness, and the number of particles were measured in the same manner as Example 1. The relative density was 91.4%, the Vickers hardness was HV54, and the number of particles was 94. The results are shown in Table 1.

### Example 4

To have the composition of 35Fe-35Pt-20BN-10C, 173.45 g of Fe powder having an average particle size of 7 μm, 605.89 g of Pt powder having an average particle size of 1 μm, 44.05 g of BN powder having an average particle size of 4 μm, and 10.66 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact. Except for this, the relative density, the Vickers hardness, and the number of particles were measured in the same manner as Example 1. The relative density was 96.2%, the Vickers hardness was HV112, and the number of particles was 61. The results are shown in Table 1.

### Example 5

To have the composition of 30Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact. Except for this, the relative density, the Vickers hardness, and the number of particles were measured in the same manner as Example 1. The relative density was 95.1%, the Vickers hardness was HV57, and the number of particles was 62. The results are shown in Table 1.

### Example 6

Except for changing the sintering temperature to 700° C., a sintered compact was obtained in the same manner as Example 5. For the resulting sintered compact, the relative density, the Vickers hardness, and the number of particles were measured in the same manner as Example 1. The relative density was 93.3%, the Vickers hardness was HV58, and the number of particles was 82. The results are shown in Table 1.

### Example 7

Except for changing the mixing time to 6 hours, a sintered compact was obtained in the same manner as Example 5. For the resulting sintered compact, the relative density, the Vickers hardness, and the number of particles were measured in the same manner as Example 1. The relative density was 90.7%, the Vickers hardness was HV50, and the number of particles was 33. The results are shown in Table 1.

### Example 8

To have the composition of 30Fe-30Pt-10BN-30C, 182.60 g of Fe powder having an average particle size of 7 μm, 637.85 g of Pt powder having an average particle size of 1 μm, 27.05 g of BN powder having an average particle size of 4 μm, and 39.27 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact. Except for this, the relative density, the Vickers hardness, and the number of particles were measured in the same manner as Example 1. The relative density was 95.5%, the Vickers hardness was HV81, and the number of particles was 97. The results are shown in Table 1.

### Example 9

To have the composition of 25Fe-25Pt-10Au-30BN-10C, 116.99 g of Fe powder having an average particle size of 7 μm, 408,33 g of Pt powder having an average particle size of 1 μm, 165.05 g of Au powder having an average particle size of 1 μm, 62.40 g of BN powder having an average particle size of 4 μm, and 10.06 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact. Except for this, the relative density, the Vickers hardness, and the number of particles were measured in the same manner as Example 1. The relative density was 96.1%, the Vickers hardness was HV67, and the number of particles was 55. The results are shown in Table 1.

### Example 10

To have the composition of 25Fe-25Pt-10Ag-30BN-10C, 116.89 g of Fe powder having an average particle size of 7 μm, 408.33 g of Pt powder having an average particle size of 1 μm, 90.31 g of Ag powder having rage particle size of 10 μm, 62.34 g of BN powder having an average particle size of 4 μm, and 10.06 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact. Except for this, the relative density, the Vickers hardness, and the number of particles were measured in the same manner as Example 1. The relative density was 95.7%, the Vickers hardness was HV59, and the number of particles was 49. The results are shown in Table 1.

### Example 11

To have the composition of 25Fe-25Pt-10Cu-30BN-10C, 121.19 g of Fe powder having an average particle size of 7 μm, 423.33 g of Pt powder having an average particle size of 1 μm, 55.16 g of Cu powder having an average particle size of 3 μm, 64.63 g of BN powder having an average particle size of 4 μm, and 10.43 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact. Except for this, the relative density, the Vickers hardness, and the number of particles were measured in the same manner as Example 1. The relative density was 95.9%, the Vickers hardness was HV69, and the number of particles was 66. The results are shown in Table 1.

### Example 12

To have the composition of 25Fe-25Pt-10Rh-30BN-10C, 119.55 g of Fe powder having an average particle size of 7 μm, 417.61 g of Pt powder having an average particle size of 1 μm, 88.12 g of Rh powder having an average particle size of 10 μm, 63.76 g of BN powder having an average particle size of 4 μm, and 10.28 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour to yield a sintered compact. Except for this, the relative density, the Vickers hardness, and the number of particles were measured in the same manner as Example 1. The relative density was 94.0%, the Vickers hardness was HV101, and the number of particles was 88. The results are shown in Table 1.

### Example 13

To have the composition of 25Fe-25Pt-10Ge-30BN-10C 112.65 g of Fe powder having an average particle size of 7 μm, 393.51 g of Pt powder having an average particle size of 1 μm, 58.61 g of Ge powder having an average particle size of 10 μm, 60.08 g of BN powder having an average particle size of 4 μm, and 9.69 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 700° C., and a holding time of 1 hour to yield a sintered compact. Except for this, the relative density, the Vickers hardness, and the number of particles were measured in the same manner as Example 1. The relative density was 97.0%, the Vickers hardness was HV96. and the number of particles was 60. The results are shown in Table 1.

### Comparative Example 1

To have the composition of 32.5Fe-32.5Pt-35BN, 157.91 g of Fe powder having an average particle size of 7 μm, 551.60 g of Pt powder having an average particle size of 1 ηm, and 75.58 g of BN powder having an average particle size of 4 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour and then subjected to HIP at an HIP pressure of 180 MPa and an HIP temperature of 900° C. to yield a sintered compact. Except for this, the relative density, the Vickers hardness, and the number of particles were measured in the same manner as Example 1. The relative density was 97.3%, the Vickers hardness was HV152, and the number of particles was 886. The results are shown in Table 1.

### Comparative Example 2

To have the composition of 30Fe-30Pt-30BN-10C, 143.73 g of Fe powder having an average particle size of 7 μm, 502.08 g of Pt powder having an average particle size of 1 μm, 63.88 g of BN powder having an average particle size of 4 μm, and 10.30 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour and then subjected to HIP at an HIP pressure of 180 MPa and an HIP temperature of 900° C. to yield a sintered compact. Except for this, the relative density, the Vickers hardness, and the number of particles were measured in the same manner as Example 1. The relative density was 98.6%, the Vickers hardness was HV166, and the number of particles was 1,120. The results are shown in Table 1.

### Comparative Example 3

To have the composition of 35Fe-35Pt-20BN-10C, 173.45 g of Fe powder having an average particle size of 7 μm, 605.89 g of Pt powder having an average particle size of 1 μm, 44.05 g of BN powder having an average particle size of 4 μm, and 10.66 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour and then subjected to HIP at an HIP pressure of 180 MPa and an HIP temperature of 900° C. to yield a sintered compact. Except for this, the relative density, the Vickers hardness, and the number of particles were measured in the same manner as Example 1. The relative density was 99.3%, the Vickers hardness was HV195, and the number of particles was 812. The results are shown in Table 1.

### Comparative Example 4

To have the composition of 25Fe-25Pt-10Ag-30BN-10C, 116.89 g of Fe powder having an average particle size of 7 μm, 408.33 g of Pt powder having an average particle size of 1 μm, 90.31 g of Ag powder having an average particle size of 10 μm, 62.34 g of BN powder having an average particle size of 4 μm, and 10.06 g of C powder having an average particle size of 3 μm were fed into a stirred media mill (media: zirconia balls) and mixed at 150 rpm for 3 hours to yield a mixed powder. The resulting mixed powder was sintered under conditions of a sintering pressure of 66 MPa, a sintering temperature of 900° C., and a holding time of 1 hour and then subjected to HIP at an HIP pressure of 180 MPa and an HIP temperature of 900° C. to yield a sintered compact. Except for this, the relative density, the Vickers hardness, and the number of particles were measured in the same manner as Example 1. The relative density was 98.9%, the Vickers hardness was HV158, and the number of particles was 1,096. The results are shown in Table 1.

### Comparative Example 5

Except for changing the HIP pressure to 150 MPa, the relative density, the Vickers hardness, and the number of particles were measured in the same manner as Comparative Example 2. The relative density was 98.0%, the \Tickers hardness was HV153, and the number of particles was 992. The results are shown in Table 1.

TABLE 1
Measured Results for Examples and Comparative Examples

| | | Raw Materials | | | | | |
|---|---|---|---|---|---|---|---|
| | Sputtering Target | | | | | Others | |
| | Target Composition. | Fe | Pt | BN | C | Element: | |
| | mol % | g | g | g | g | Particle size | g |
| Ex. 1 | 35Fe—35Pr—30BN | 172.79 | 603.60 | 65.83 | | | |
| Ex. 2 | 32.5Fe—32.5Pt—35BN | 157.91 | 551.60 | 75.58 | | | |
| Ex. 3 | 27.5Fe—27.5Pt—45BN | 129.51 | 452.40 | 94.19 | | | |
| Ex. 4 | 35Fe—35Pt—20BN—10C | 173.45 | 605.89 | 44.05 | 10.66 | | |
| Ex. 5 | 30Fe—30Pt—30BN—10C | 143.73 | 502.08 | 63.88 | 10.30 | | |
| Ex. 6 | 30Fe—30Pt—30BN—10C | 143.73 | 502.08 | 63.88 | 10.30 | | |
| Ex. 7 | 30Fe—30Pt—30BN—10C | 143.73 | 502.08 | 63.88 | 10.30 | | |
| Ex. 8 | 30Fe—30Pt—10BN—30C | 182.60 | 637.85 | 27.05 | 39.27 | | |
| Ex. 9 | 25Fe—25Pt—10Au—30BN—10C | 116.99 | 408.33 | 62.40 | 10.06 | Au: 1 μm | 165.05 |
| Ex. 10 | 25Fe—25Pt—10Ag—30BN—10C | 116.89 | 408.33 | 62.34 | 10.06 | Ag: 10 μm | 90.31 |
| Ex. 11 | 25Fe—25Pt—10Cu—30BN—10C | 121.19 | 423.33 | 64.63 | 10.43 | Cu: 3 μm | 55.16 |
| Ex. 12 | 25Fe—25Pt—10Rh—30BN—10C | 119.55 | 417.61 | 63.76 | 10.28 | Rh: 10 μm | 88.12 |
| Ex. 13 | 25Fe—25Pt—10Ge—30BN—10C | 112.65 | 393.51 | 60.08 | 9.69 | Ge: 10 μm | 58.61 |
| Comp. Ex. 1 | 32.5Fe—32.5Pt—35BN | 157.91 | 551.60 | 75.58 | | | |
| Comp. Ex. 2 | 30Fe—30Pt—30BN—10C | 143.73 | 502.08 | 63.88 | 10.30 | | |
| Comp. Ex. 3 | 35Fe—35Pt—20BN—10C | 173.45 | 605.89 | 44.05 | 10.66 | | |
| Comp. Ex. 4 | 25Fe—25Pt—10Ag—30BN—10C | 116.89 | 408.33 | 62.34 | 10.06 | Ag: 10 μm | 90.31 |
| Comp. Ex. 5 | 30Fe—30Pt—30BN—10C | 143.73 | 502.08 | 63.88 | 10.30 | | |

| | | Sintering | | | | Results | | |
|---|---|---|---|---|---|---|---|---|
| | | Conditions | | HIP Conditions | | Relative | | |
| | Mixing | Pressure | Temp. | Pressure | Temp. | density | HV | Number of |
| | Conditions | (MPa) | (° C.) | (MPa) | (° C.) | (%) | (—) | Particles |
| Ex. 1 | 150 rpm 3 h | 66 | 900 | — | — | 95.0 | 104 | 67 |
| Ex. 2 | 150 rpm 3 h | 66 | 900 | — | — | 94.1 | 66 | 77 |
| Ex. 3 | 150 rpm 3 h | 66 | 900 | — | — | 91.4 | 54 | 94 |
| Ex. 4 | 150 rpm 3 h | 66 | 900 | — | — | 96.2 | 112 | 61 |
| Ex. 5 | 150 rpm 3 h | 66 | 900 | — | — | 95.1 | 57 | 62 |
| Ex. 6 | 150 rpm 3 h | 66 | 700 | — | — | 93.3 | 58 | 82 |
| Ex. 7 | 150 rpm 6 h | 66 | 900 | — | — | 90.7 | 50 | 33 |
| Ex. 8 | 150 rpm 3 h | 66 | 900 | — | — | 95.5 | 81 | 97 |
| Ex. 9 | 150 rpm 3 h | 66 | 900 | — | — | 96.1 | 67 | 55 |
| Ex. 10 | 150 rpm 3 h | 66 | 900 | — | — | 95.7 | 59 | 49 |
| Ex. 11 | 150 rpm 3 h | 66 | 900 | — | — | 95.9 | 69 | 66 |
| Ex. 12 | 150 rpm 3 h | 66 | 900 | — | — | 94.0 | 101 | 88 |
| Ex. 13 | 150 rpm 3 h | 66 | 700 | — | — | 97.0 | 96 | 60 |
| Comp. Ex. 1 | 150 rpm 3 h | 66 | 900 | 180 | 900 | 97.3 | 152 | 886 |
| Comp. Ex. 2 | 150 rpm 3 h | 66 | 900 | 180 | 900 | 98.6 | 166 | 1120 |
| Comp. Ex. 3 | 150 rpm 3 h | 66 | 900 | 180 | 900 | 99.3 | 195 | 812 |
| Comp. Ex. 4 | 150 rpm 3 h | 66 | 900 | 180 | 900 | 98.9 | 158 | 1096 |
| Comp. Ex. 5 | 150 rpm 3 h | 66 | 900 | 150 | 900 | 98.0 | 153 | 992 |

### Disscussion

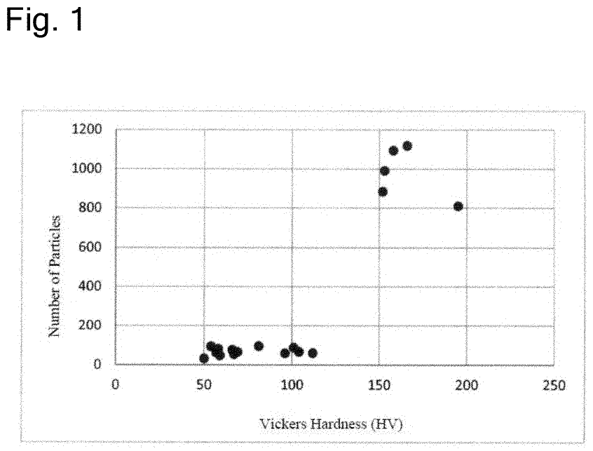

FIG. 1. plots the Vickers hardness and the number of particles. FIG. 1 reveals that the number of particles, regardless of the composition of Fe-Pi-BN-based sputtering targets, becomes extremely large as 800 or more at the Vickers hardness exceeding HV150 and remarkably small as 100 or less at the Vickers hardness of HV150 or less.

1. An Fe-Pt-BN-based sputtering target having a Vickers hardness of 150 or less.

2. The Fe-Pt-BN-based sputtering target according to claim 1, comprising 20 mol % or more and less than 40 mol % of Pt and 25 mol % or more and 50 mol % or less of BN, with the balance being Fe and incidental impurities.

3. The Fe-Pt-BN-based sputtering target according to claim 1, comprising 20 mol % or more and less than 40 mol % of Pt, 10 mol % or more and less than 50 mol % of BN, and more than 0 mol % and 30 mol % or less of C, with the balance being Fe and incidental impurities, wherein a total content of BN and C is 25 mol % or more and 50 mol % or less.

4. The Fe-Pt-BN-based sputtering target according to claim 1, comprising 20 mol % or more and less than 40 mol % of Pt and 25 mol % or more and 50 mol % or less of BN, and a total content of 15 mol % or less of one or more elements selected from Au, Ag, B, Cr, Cu, Ge, Ir, Ni, Pd, Rh, and Ru, with the balance being Fe and incidental impurities.

5. The Fe-Pt-BN-based sputtering target according to claim 1, comprising 20 mol % or more and less than 40 mol % of Pt, 10 mol % or more and less than 50 mol % of BN, and more than 0 mol % and 30 mol % or less of C, and a total content of 15 mol % or less of one or more elements selected from Au, Ag, B, Cr, Cu, Ge, Ir, Ni, Pd, Rh, and Ru, with the balance being Fe and incidental impurities, wherein a total content of BN and C is 25 mol % or more and 50 mol % or less.

6. The Fe-Pt-BN-based sputtering target according to claim 1, having a relative density of 90% or more.

7. A method of producing the Fe-Pt-BN-based sputtering target according to claim 2, comprising
feeding Fe powder, Pt powder, and BN powder into a stirred media mill and mixing at 100 rpm or more and 300 rpm or less for 1 hour or more and 6 hours or less to obtain a raw material powder mixture; and
sintering the raw material powder mixture, wherein
hot isostatic pressing (HIP) is not performed.

8. A method of producing the Fe-Pt-BN-based sputtering target according to claim 3, comprising
feeding Fe powder, Pt powder, BN powder, and C powder into a stirred media mill and mixing at 100 rpm or more and 300 rpm or less for 1 hour or more and 6 hours or less to obtain a raw material powder mixture; and
sintering the raw material powder mixture, wherein
hot isostatic pressing (HIP) is not performed.

9. The Fe-Pt-BN-based sputtering target according to claim 2, having a relative density of 90% or more.

10. The Fe-Pt-BN-based sputtering target according to claim 3, having a relative density of 90% or more.

11. The Fe-Pt-BN-based sputtering target according to claim 4, having a relative density of 90% or more.

12. The Fe-Pt-BN-based sputtering target according to claim 5, having a relative density of 90% or more.
